(19) United States
(12) Patent Application Publication
(10) Pub. No.: US 2002/0170882 A1
(43) Pub. Date: Nov. 21, 2002

(54) Method and apparatus for supporting substrate

(76) Inventor: Fuminori Akiba, Narita-shi (JP)

Correspondence Address: APPLIED MATERIALS, INC., 2881 SCOTT BLVD. M/S 2061, SANTA CLARA, CA, 95050, US

(21) Appl. No.: 10/083,700

(22) Filed: Feb. 26, 2002

(30) Foreign Application Priority Data
Feb. 28, 2001 (JP) P2001-055584

(51) Int. Cl. C23F 1/00; C23C 14/32; C23C 16/00; H01L 21/306

(52) U.S. Cl. 216/67; 204/298.15; 204/192.1; 156/345.51; 156/345.52; 156/345.53; 118/724; 118/725; 118/728

(57) ABSTRACT

The present invention is a substrate support method wherein a voltage is applied to the electrostatic chuck of a substrate support apparatus equipped in a chamber, thereby using a coulomb force to adsorb and support a substrate mounted on the semiconductor chuck. This substrate support method includes (1) a voltage increasing step that increases the voltage applied to the electrostatic chuck from a base value to a first value that is required for adsorbing the substrate, and (2) a first voltage maintenance step that maintains at the first value the voltage that was increased in the voltage increasing step, and (3) the voltage is increased in steps in the voltage increasing step from the base value to the first value.

### BACKGROUND OF THE INVENTION

1. Field of the Invention

The present invention relates to a substrate support method and a substrate support apparatus, wherein a substrate is adsorbed and supported by an electrostatic chuck.

2. Description of the Related Art

Semiconductor manufacturing equipment known as sputtering equipment is generally equipped with a processing chamber that provides a low pressure vacuum, where a substrate support apparatus for supporting a semiconductor wafer (a substrate) is provided within this processing chamber. The substrate support apparatus is provided with a base member, which contains a heater or a cooler, and, at the top part of this base member, is equipped with an electrostatic chuck that adsorbs and supports a semiconductor wafer through a coulomb force when an electric voltage is applied. Furthermore, the base member is provided with gas introduction ducts for introducing a gas for thermal conduction, where the gas for thermal conduction that is introduced through these gas introduction ducts heats the semiconductor wafer that is mounted on the electrostatic chuck.

In the substrate support method that uses this type of substrate support apparatus, the semiconductor wafers that are transported to the electrostatic chuck are not necessarily flat, and but warped wafers might be transported as well. However, supporting on the electrostatic chuck a warped semiconductor wafer and then processing the wafer through for example, sputtering, in that state, may destabilize the process. Consequently, in the conventional substrate support method, once a high voltage is applied to the electrostatic chuck whereon a semiconductor wafer has been mounted, thereby applying a strong adhesive force to the semiconductor wafer in order to correct the warp, the voltage is then reduced in order to support the wafer through adsorbing with a weaker force.

### SUMMARY OF THE INVENTION

As the result of investigations into the conventional technology, described above, the inventors discovered problems such as described below. In other words, in the conventional substrate support method, described above, the semiconductor wafers supported on the electrostatic chamber have sometimes experienced thermal fractures.

The present invention was created in order to solve the problems described above and an object of the present invention is to provide a semiconductor support method and a semiconductor support apparatus that is able to reduce the risk of thermal fractures occurring in a substrate when the substrate is supported on an electrostatic chuck.

In order to achieve the object described above, the inventor has diligently researched the causes of thermal fractures in substrates, and has obtained the knowledge described below.

In other words, as is shown in FIG. 4, when a substrate 104 that is warped is mounted on an electrostatic chuck 102 of a substrate support apparatus 100, and, as shown in FIG. 5, a conventional substrate support method is used, a high voltage V_{c} of about 900 V is first applied to the electrostatic chuck 102 in order to correct the warp, adsorbing the substrate 104 through a strong force to the electrostatic chuck 102. The thermally conductive gas that is then supplied to the center part of the substrate 104 suddenly increases the temperature in a broad area of the substrate 104.

The substrate 104 was first adsorbed to the electrostatic chuck 102 by a strong force, so the inventor wondered if the adhesive force restricted the elongation of the substrate 104 in the direction of its primary surface, thus preventing adequate relaxation of the thermal expansion of the substrate 104 accompanying its rapid increase in temperature. Given this, the inventor wondered if the strain that occurs within the substrate 104 might be the cause of the thermal fracturing of the substrate 104.

Given the above, the inventor discovered that it was possible to reduce the risk of occurrence of thermal fracturing by providing time over which the voltage is increasingly applied to the electrostatic chuck, doing so by, for example, applying the voltage in steps. The inventor assumes that this is because the substrate is allowed to elongate in the direction of its primary surface because the substrate is adsorbed gradually to the electrostatic chuck, thereby allowing adequate relaxation of the thermal expansion accompanying the sudden increase in temperature. The present invention was created based on this knowledge.

In other words, the present invention is a substrate support method that adsorbs and supports through a coulomb force a substrate mounted on an electrostatic chuck by applying a voltage to the electrostatic chuck of the substrate support apparatus equipped in a chamber. The substrate support method comprises (1) a voltage increasing step wherein the voltage that is applied to the electrostatic chuck is increased from a base value to a first value that is required for adsorbing the substrate, and (2) a first voltage maintenance step wherein the voltage that was increased in the increasing voltage step is maintained at the first value, where (3) in the voltage increasing step, the voltage is increased in steps from the base value to the first value.

In this substrate support method, the risk of thermal fracturing occurring in the substrate is reduced. This is assumed to be because the substrate is allowed to elongate in the direction of its primary surface because the substrate is gradually adsorbed to the electrostatic chuck because the voltage that is applied to the electrostatic chuck is increased in steps from a base voltage to a first voltage, thereby adequately relaxing the thermal expansion that accompanies the increase in temperature of the substrate.

The substrate support method according to the present invention further comprises a second voltage maintenance step wherein the voltage that was maintained at a first value in the first voltage maintenance step is reduced to a second value, which is between the first value and the base value, and maintained at the second value. By doing this, the warp in the substrate is corrected in the first voltage maintenance step, and, in the second voltage maintenance step, the adsorption of the substrate is maintained at the voltage of the second value, which is less than the first value.

The present invention is a substrate support method wherein a voltage is applied to an electrostatic chuck in a substrate support apparatus that is equipped in a chamber to adsorb and support a substrate that is mounted by a coulomb force on a electrostatic chuck. This substrate support method comprises (1) a voltage increasing step wherein a voltage that is applied to an electrostatic chuck is increased from a base value to a first value that is required for adsorbing the substrate, and (2) a first voltage maintenance step where the voltage that was increased in the voltage increasing step is maintained at a first value, where (3) the time required for increasing the voltage in the voltage increasing step from the base value to the first value is longer than the time in the first voltage maintenance step wherein the voltage is maintained at the first value.

In this substrate support method the risk of occurrence of thermal fracturing in the thermal substrate is reduced. This is assumed to be because the substrate is allowed to elongate along the direction of its primary surface because the substrate is gradually adsorbed on the electrostatic chuck because, when the voltage that is applied to the electrostatic chuck is increased from the base value to the first value, through increasing over a time that is longer than the time for maintaining the voltage at the first value in the first voltage maintenance step, in order to adequately relax the thermal expansion that occurs as the temperature of the substrate increases.

In the substrate support method according to the present invention, preferably the voltage is increased in steps from the base value to the first value in the voltage increasing step.

Additionally, the substrate support process according to the present invention also comprises a second voltage maintenance step wherein the voltage that was maintained at the first value in the first voltage maintenance step is reduced to a second value that is between the first value and the base value and maintained at the second value. By doing so, the substrate warp is corrected in the first voltage maintenance step, and in the second voltage maintenance step, the substrate adsorption is maintained at the voltage of a second value that is smaller than the first value.

In addition, the substrate support method according to the present invention can also contain a gas supply step that supplies, to the substrate on the electrostatic chuck, a gas for thermal conduction. In this way, the present invention is suited to a substrate support method of a gas heating type, wherein the temperature of the substrate is increased by supplying, to the substrate a gas, for thermal conduction.

The substrate support apparatus according to the present invention is an apparatus for effectively implementing the substrate support method according to the present invention, as described above. The substrate support apparatus according to the present invention comprises (1) a base member that is equipped in a chamber and that has gas introduction ducts for introducing a gas for thermal conduction, (2) an electrostatic chuck that is equipped at the top of the base member and that adsorbs and secures a substrate through a coulomb force by the application of a voltage, (3) a power supply apparatus for applying a voltage to the electrostatic chuck, and (4) a control means for controlling the power supply device in order to increase in steps the voltage that is applied to the electrostatic chuck from a base value to a first value that is required for adsorbing the substrate.

In the substrate support apparatus according to the present invention, the control means controls the power supply device so as to reduce the voltage that was maintained at the first value to a second value that is between the first value and the base value, and maintains the voltage at the second value.

The substrate support apparatus of this invention is equipped with a (1) a base member that is equipped in the chamber and that has gas introduction ducts for guiding the gas for thermal conduction, (2) an electrostatic chuck that is equipped at the top of the base member and that adsorbs and supports a substrate through a coulomb force by the application of a voltage, (3) a power supply device for applying a voltage to the electrostatic chuck, and (4) a control means for controlling the power supply device in order to not only increase the voltage that is applied to the electrostatic chuck from a base value to a first value that is required for adsorbing the substrate but also to maintain the voltage at the first value, where the control means controls the power supply device so that a time longer than the time over which the voltage is maintained at the first value is taken to increase the voltage from the base value to the first value.

In the substrate support apparatus according to the present invention, the power supply device is controlled so that the voltage that was maintained at the first value is reduced to a second value that is between the first value and the base value, and maintained at the second value.

In the substrate support apparatus according to the present invention, gas storage grooves that store gas for thermal conduction that has been introduced from the gas introduction ducts, and that are connected to the gas introduction ducts, are fabricated in the top surface part of the electrostatic chuck.

In addition, in the substrate support apparatus according to the present invention, the gas storage grooves have parts that extend radially towards the peripheral edges of the electrostatic chuck.

The present invention can be understood even more completely through the detailed explanations and the attached drawings, below. These are presented as examples only, and should not be considered to be limiting the present invention.

Furthermore, the range of application of the present invention is clear from the detailed explanations below. However, even though the detailed explanations and the specific examples of embodiment show preferred examples of embodiment of the present invention, these are only presented as examples, and, from the detailed explanations, it is clearly self-evident to individuals in the industry that there can be a variety of different forms and improvements within the concept and scope of the present invention.

### BRIEF DESCRIPTION OF THE DRAWINGS

FIG. 1 is a structural view showing schematically an example of embodiment of a sputtering equipment equipped with the substrate support apparatus according to the present invention;

FIG. 2 is a graph showing an example of the signals that are sent to a power supply device from a control device in order to control the power supply device to apply voltages to the electrostatic chuck FIG. 3 is a cross-sectional view along the line III-III in FIG. 1;

FIG. 4 is a schematic view showing the state wherein a semiconductor wafer that is warped is mounted on the electrostatic chuck of the substrate support apparatus; and

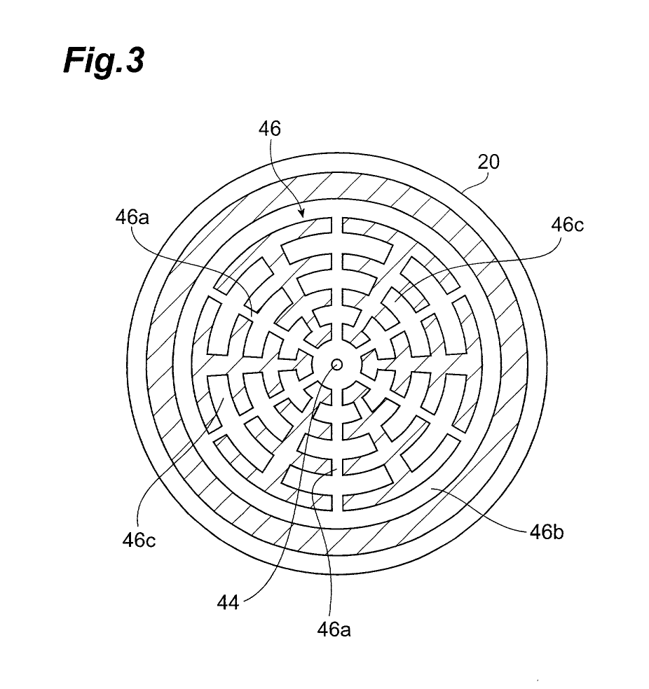

FIG. 5 is a graph showing the time profile of the voltage applied to the electrostatic chuck in a conventional substrate support method.

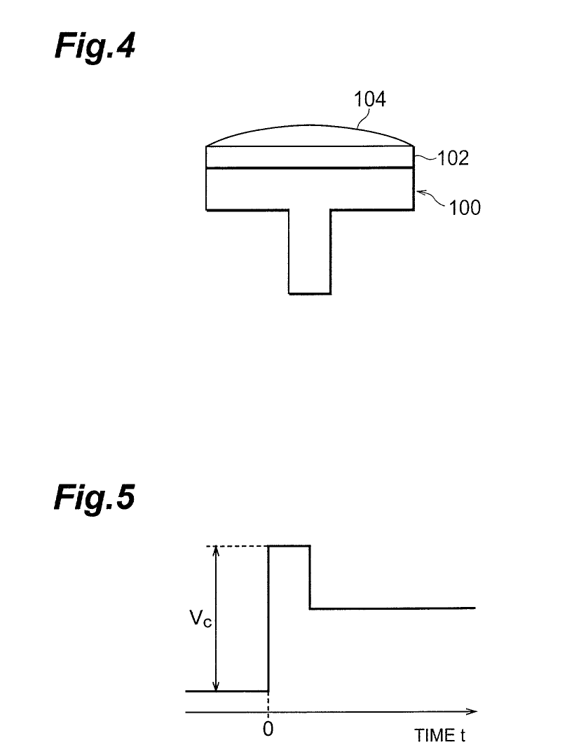

### DESCRIPTION OF THE PREFERRED EMBODIMENTS

Detailed descriptions of examples of embodiment of the present invention will be explained below, referencing the attached figures. Note that in the explanations of the figures, similar parts are given the same symbols, and redundant explanations are omitted.

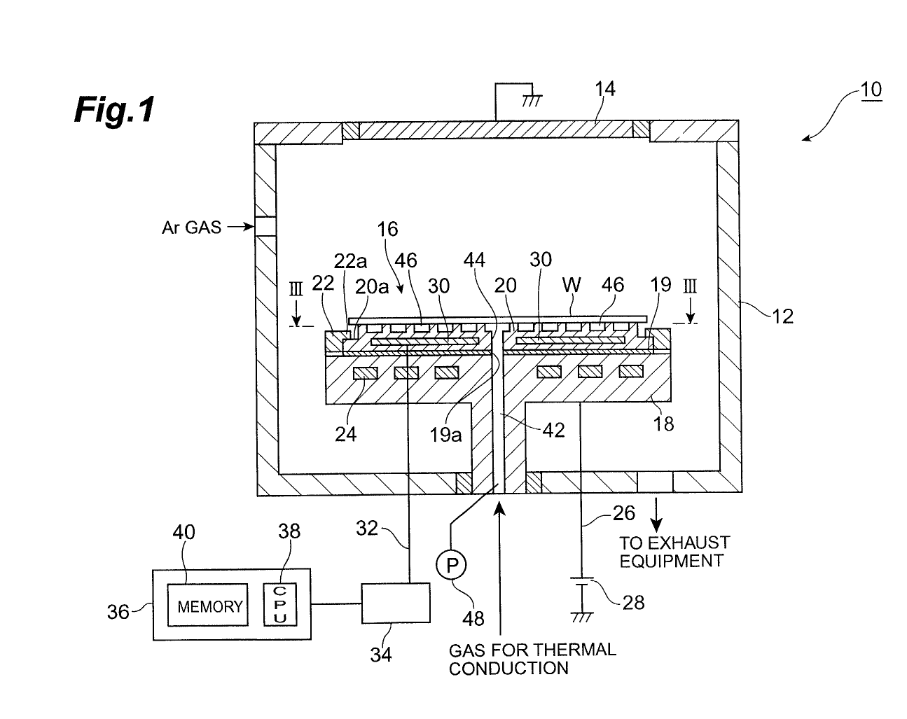

FIG. 1 is a structural view showing, schematically, sputtering equipment equipped with a substrate support apparatus according to the present invention. As shown in the figure, the sputtering equipment 10 is equipped with a processing chamber 12 wherein the pressure is reduced to a vacuum, where the top part of this processing chamber 12 is equipped with a target 14 that comprises a cathode. Additionally, a substrate support apparatus 16 for supporting a semiconductor wafer (substrate) W is equipped in the processing chamber 12.

The substrate support apparatus 16 is equipped facing and parallel to the target 14, and is equipped with base member 18, that is circular in its horizontal cross section and that comprises an anode, an electrostatic chuck 20 that is equipped at the top of said base member 18 across a sheet 19 for thermal conduction, that adsorbs and secures a semiconductor wafer W, and that is circular in its horizontal cross section, and a ring-shaped holder 22 that secures this electrostatic chuck 20 to the base member 18. On the periphery of the electrostatic chuck 20 is formed a step part 20a, where, when a protruding part 22a that is equipped on the inside surface of the holder 22 rests on the step part 20a, the electrostatic chuck 20 is secured to the base member 18 by bolting the holder 22 to the base member 18.

The base member 18 is fabricated from a metal such as stainless steel, and contains a nickel-chromium wire 24 as a heater. Additionally, this base member 18 is connected to a direct current power supply 28 through an electric lead wire 26, where, when an electric current is applied to the base member 18 by this direct current power supply 28, a plasma is generated between the base member 18 as an anode and the target 14 as a cathode.

The electrostatic chuck 20 is fabricated from a ceramic such as alumina. The electrostatic chuck 20 contains an electrode 30, where this electrode 30 is connected through the electric lead wire 32 to a power supply device 34. When an electric current is applied to the electrode 30 by the power supply device 34 a coulomb force is generated between the electrostatic chuck 20 and the semiconductor wafer W, so the semiconductor wafer W is adsorbed to the electrostatic chuck 20. A control device 36, for controlling the voltage that is supplied to the electrode 30, is connected to the power supply device 34.

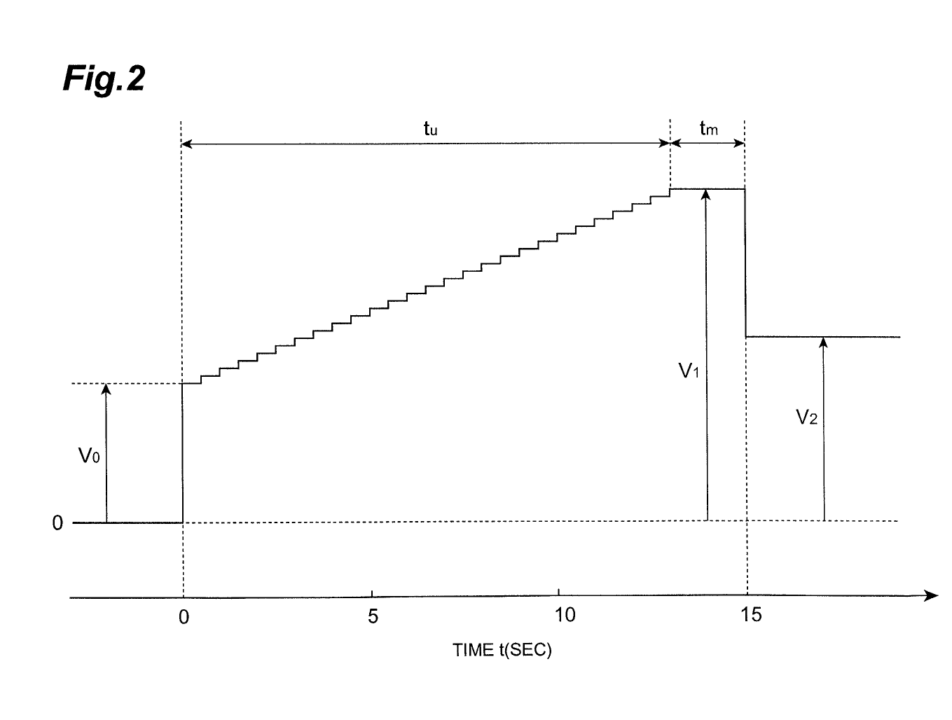

The control device 36 has a CPU 38 and a memory 40. As is shown in FIG. 2, the memory 40 contains a program for generating signals to drive the power supply device 34 in order to increase the voltage that is applied to the electrode 30 of the electrostatic chuck 20 from 0 volts (the base value) to V₁ volts (the first value) required for adsorbing semiconductor wafer W, increasing the voltage in steps, and, after the voltage is maintained at the V₁ voltage for a specific time Tₘ, dropping the voltage to a V₂ voltage (second value) between 0 volts and V₁ volts, and maintaining the voltage at V₂ volts. In this program, the time tᵤ required for increasing the voltage from 0 volts to V₁ volts is set to be longer than the time tₘ for maintaining the voltage at V₁ volts.

This base member 18 is equipped with gas introduction ducts 42 for guiding the gas for thermal conduction that is introduced from a gas supply source, not shown. These gas introduction ducts 42 extend in a direction that is perpendicular to the center of said base member 18, and are open at the top.

Gas introduction ducts 44, which are connected to gas introduction ducts 42, which extend in a direction perpendicular to the center part, and which are open at the time, are equipped in electrostatic chuck 20. Additionally, in the top part of the electrostatic chuck 20 are formed gas storage grooves 46 for storing the gas for thermal conduction that is introduced from the aforementioned gas introduction ducts 44, and are connected to the gas introduction ducts 44. The gas storage grooves 46, as shown in FIG. 3, comprise multiple linear groove parts 46a that extend radially from, and connect to, the gas introduction duct 44, a ring-shaped groove part 46b connected to these linear groove parts 46a, and fabricated on the inner side of this ring shaped groove part 46, multiple arc-shaped grooves 46c, which each have end parts. In this way, the gas storage grooves 46 are structured from linear groove parts 46a, ring-shaped groove parts 46b, and arched groove parts 46c, and thus can supply efficiently the gas for thermal conduction from the gas introduction ducts 46 to the semiconductor wafer W, from the inside to the outside thereof.

Note that the gas introduction ducts 42 are connected to a pressure meter 48 for measuring the supply pressure of the gas for thermal conduction. The sheet 19 for thermal conduction is fabricated from a metal that has elasticity, such as aluminum, and in the center thereof are equipped gas introduction holes 19a, connected to the gas introduction ducts 42 and 44.

The support method for the semiconductor wafer W using the substrate support apparatus 16 when a thin film fabrication process is performed using the sputtering equipment 10 structured as described above will be explained below.

First a semiconductor wafer W is introduced into the processing chamber 12 and mounted at a specific location on the electrostatic chuck 20. Next the application of voltage to the electrode 30 of the electrostatic chuck 20 is begun. Here, as an example, an explanation will be given of the process for adsorbing and supporting a semiconductor wafer W on an electrostatic chuck 20 by applying a voltage that is a maximum of 900V when performing a sputtering process after increasing the temperature of the semiconductor wafer W to about 500° C. after adsorbing a semiconductor wafer that is 200 mm in diameter and that has a warp that is no less than 150 μm. As is shown in FIG. 2, at time t=0 sec, a signal is sent from the control device 36 to the power supply device 34 to apply at first a voltage of 380 volts (V₀) to the electrode 30 of the electrostatic chuck 20. At the same time, a gas for thermal conduction is supplied to the gas storage grooves 46 through the gas introduction ducts 42, the gas introduction hole 19a, and the gas introduction holes 44 from a gas supply source, not shown.

By doing so, the temperature of the semiconductor wafer W can be increased efficiently. Note that helium gas, argon gas, nitrogen gas, or other gases with superior thermal conversion rates can be used as the gas for thermal conduction.

Next, a signal for increasing in steps the voltage applied to the electrode 30 of the electrostatic chuck 20 at a rate of 20 volts per 0.5 sec is sent from the control device 36 to the power supply device 34. When this is done, the voltage that is applied to the electrostatic chuck 20 from the power supply device 34 increases in steps, gradually adsorbing the semiconductor wafer W onto the electrostatic chuck 20. Furthermore, after 13 seconds (tᵤ) elapses, at time t=13 sec, and the voltage arrives at 900 V (V₁), at which time a signal for maintaining the voltage at 900V for only two seconds (tₘ) is sent from the control device 36 to the power supply device 34. By doing so, the voltage that is applied to the electrostatic chuck 20 is maintained at the high voltage of 900V, and the warp in the semiconductor wafer W is corrected by the strong adhesive force. Moreover, at time t=15 seconds, a signal for dropping the voltage to 500V (V₂) and maintaining the voltage at 500V is sent to the power supply device 34 from the control device 36. At this time, because the warp in the semiconductor wafer W has been corrected by the application of the voltage at 900V, it is possible to adsorb the semiconductor wafer W securely, and to support the same, even at the lower voltage of 500V.

Next, the vacuum exhaust system connected to the processing chamber 12 is actuated, reducing the pressure within the processing chamber 12 to a specific vacuum level. Furthermore, argon gas (Ar gas) is introduced into the processing chamber 12, and the DC power supply 29 is actuated to apply a voltage between the base member 18, as the anode, and the target 14, as the cathode. When this is done, a plasma discharge occurs between these electrodes, and argon ions impinge upon the target 14 to cause the particles sputtered therefrom to be deposited onto the semiconductor wafer W to form a thin film.

In the above, when in the substrate support method according to this example of embodiment the voltage applied to the electrode 30 of the electrostatic chuck 20 is increased to V₁ volts, the voltage is increased in steps over a time period tᵤ that is longer than the time period tₘ over which the voltage is maintained at V₁ volts, and thus the risk of thermal fracturing occurring in the semiconductor wafer W is reduced. This is assumed to be because it is possible to relax adequately the thermal expansion that accompanies the increase in temperature through allowing the semiconductor wafer W to elongate in the direction of its primary surface by gradually adsorbing the semiconductor wafer W to the electrostatic chuck 20.

Note that the present invention is not limited to the example of embodiment described above, and that is can be modified in various ways.

For example, in the example of embodiment described above, an initial voltage (V₀) was applied at first at a Time t=0 sec, and afterwards the voltage was increased in steps at a constant rate. However, the voltage can be increased in steps with a constant rate from time t=0 sec as well. However, when the initial voltage (V₀) is first applied at time t=0 sec, the throughput can be increased by reducing the time interval tᵤ required for increasing the voltage. In the example described above, a voltage of 380 volts was first applied at time t=0 sec when applying a maximum voltage of 900 volts; however, an initial voltage (V₀) of up to about 400 volts can be applied at the time t=0 sec.

Additionally, the increase rate by which to increase the voltage in steps can be set as desired. However, when one considers throughput and the relaxation of thermal expansion, the voltage increase rate of about 20 volts/0.5 seconds, as described above, is preferable.

In addition, the voltage increase rate can also be changed rather than being constant. Furthermore, the voltage increase need not be done in steps, but the voltage can alternatively be increased continuously.

Furthermore, while the gas storage grooves 46 were structured from linear groove parts 46a, ring groove parts 46b, and arch groove parts 46c, fabricated on the top surface of the electrostatic chuck 20, the gas storage grooves 46 are not limited in particular thereto. However, in order to supply the gas for thermal conduction to the wide range of the semiconductor wafer W, it is preferable for at least some part, or all parts, of the gas storage grooves 46 to extend radially towards the edges of the electrostatic chuck 20.

Furthermore, although the substrate support apparatus 16 of the present invention is equipped in the sputtering equipment 10, the substrate support apparatus can, of course, be applied to equipment other than sputtering equipment.

Using the present invention, as described in detail above, a substrate support method and a substrate support apparatus able to reduce the risk of thermal fracturing occurring in substrates when supporting substrates in an electrostatic chuck are provided.

From the prescription of the present invention, above, it is clear that a variety of modifications can be made to the present invention. These modifications cannot be seen as deviations from the concept or range of the

present invention, and all improvements that are obvious to one skilled in the art are included in the scope of the claims, below.

What is claimed is:

1. A substrate support method that adsorbs and supports a substrate mounted on an electrostatic chuck through a coulomb force by applying a voltage to said electrostatic chuck of a substrate support apparatus equipped in a chamber, comprising;
a voltage increasing step that increases the voltage that is applied to said electrostatic chuck from a base value to a first value that is required for adsorbing said substrate; and
a first voltage maintenance step that maintains at said first value the voltage that was increased in said voltage increasing step,
wherein the voltage is increased in steps from said base value to said first value in said voltage increasing step.

2. The substrate support method according to claim 1, further comprising a second voltage maintenance step that lowers the voltage that was maintained at said first value in said first voltage maintenance step to a second value between said first value and said base value and maintain said voltage at said second value.

3. The substrate support method according to claim 1, further comprising a gas supply step that supplies a gas for thermal conduction to said substrate on said electrostatic chuck.

4. A substrate support method that adsorbs and supports a substrate mounted on an electrostatic chuck through a coulomb force by applying a voltage to said electrostatic chuck of a substrate support apparatus equipped in a chamber, comprising;
a voltage increasing step that increases the voltage that is applied to said electrostatic chuck from a base value to a first value that is required for adsorbing said substrate; and
a first voltage maintenance step that maintains at said first value the voltage that was increased in said voltage increasing step,
wherein the time required to increase the voltage in said voltage increasing step from said base value to said first value is longer than the time over which the voltage is maintained at said first value in said first voltage maintenance step.

5. The substrate support method according to claim 4, wherein said voltage is increased in steps from said base value to said first value in said voltage increasing step.

6. The substrate support method according to claim 4, further comprising a second voltage maintenance step that reduces the voltage that was maintained at said first value in said first voltage maintenance step to a second value that is between said first value and said base value and sustains said voltage at said second value.

7. The substrate support method according to claim 4, further comprising a gas supply step that supplies a gas for thermal conduction to said substrate on said electrostatic chuck.

8. A substrate support apparatus comprising:
a base member that is equipped in a chamber and that has gas introduction ducts for introducing a gas for thermal conduction;
an electrostatic chuck that is equipped on said base member and that adsorbs and secures a substrate through coulomb force by the application of a voltage;
a power supply device for applying a voltage to said electrostatic chuck; and
a control means for controlling said power supply device so that the voltage that is applied to said electrostatic chuck is increased in steps from a base value to a first value that is required for adsorbing said substrate, and maintained at said first value.

9. The substrate support apparatus according to claim 8, wherein said control means controls said power supply device so that the voltage that has been maintained at said first value is reduced to a second value that is between said first value and said base value and maintained at said second value.

10. The substrate support apparatus according to claim 8, wherein gas storage grooves are fabricated in the top surface part of said electrostatic chuck so as to be connected to the gas introduction ducts for storing said gas for thermal conduction introduced from said gas introduction ducts.

11. The substrate support apparatus according to claim 10, wherein said gas storage grooves have parts that extend radially towards to peripheral edges of said electrostatic chuck.

12. A substrate support apparatus comprising:
a base member that is equipped in a chamber and that has gas introduction ducts for introducing a gas for thermal conduction;
an electrostatic chuck that is equipped on said base member and that adsorbs and secures a substrate through coulomb force by the application of a voltage;
a power supply device for applying a voltage to said electrostatic chuck; and
a control means for controlling said power supply device so that the voltage that is applied to said electrostatic chuck is increased in steps from a base value to a first value that is required for adsorbing said substrate, and maintained at said first value,
wherein said control means controls said power supply device so that the time required to increase said voltage from said base value to said first value is longer than the time over which the voltage is maintained at said first value.

13. The substrate support apparatus according to claim 12, wherein said control means controls said power supply device so that the voltage that was maintained at said first value is reduced to a second value between said first value and a base value, and is maintained at said second value.

14. The substrate support apparatus according to claim 12, wherein gas storage grooves are fabricated in the top surface part of said electrostatic chuck so as to be connected to the gas introduction ducts for storing said gas for thermal conduction introduced from said gas introduction ducts.

15. The substrate support apparatus according to claim 14 wherein said gas storage grooves have parts that extend radially towards the peripheral edges of said electrostatic chuck.
